(19) United States
(12) Patent Application Publication
(10) Pub. No.: US 2009/0251968 A1
(43) Pub. Date: Oct. 8, 2009

(54) Integrated circuit having a base structure and a nanostructure

(76) Inventors: Christoph Andreas Kleint, Dresden (DE); Josef Willer, Riemerling (DE)

Correspondence Address: SLATER & MATSIL, L.L.P., 17950 PRESTON ROAD, SUITE 1000, DALLAS, TX, 75252, US

(21) Appl. No.: 12/099,522

(22) Filed: Apr. 8, 2008

(51) Int. Cl. H01L 21/00; G11C 16/04

(52) U.S. Cl. 365/185.17; 438/121; 257/E21.001

(57) ABSTRACT

In an embodiment, an integrated circuit may include a metallically conductive structure, a base structure having a crystal orientation, the base structure being adjacent to the metallically conductive structure, and a nanostructure disposed on the base structure, the nanostructure having substantially the same crystal orientation as the base structure.

### TECHNICAL FIELD

Embodiments of the present invention relate generally to an integrated circuit having a base structure and a nanostructure.

### BACKGROUND

Nanostructures are used in numerous integrated circuits to provide electrically active components that occupy a small volume. The overall size of integrated circuits can therefore be reduced, or alternatively, an increased number of active electronic components can be constructed in an integrated circuit of any given size. Vertically extending elongate structures may be grown from a pre-existing material starting structure, sometimes referred to as a seed point, using conventional epitaxial methods. Only those seed points whose material substance can be incorporated into the existing bed, or substrate, of the integrated circuit can be used. Theoretically, an integrated circuit can be made from any material which can be arranged to conduct, for example conductive carbon, but in practice integrated circuits including vertically extending elongate structures are conventionally made from semiconductor material thereby allowing a tradeoff between conductivity within the overall device and ease of manufacture of the integrated circuit with a vertically extending elongate structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a computer system having a memory cell arrangement in accordance with an embodiment;

FIG. 2 shows a memory cell field in accordance with an embodiment;

FIG. 3 shows an example of the memory cell field of FIG. 2 in accordance with an embodiment;

FIG. 4 shows a nanostructure arrangement of an embodiment in cross section, as it might be incorporated into an integrated circuit;

FIG. 5 shows a nanostructure arrangement of another embodiment in cross section, as it might be incorporated into an integrated circuit;

FIG. 6 shows a nanostructure arrangement of another embodiment, as it might be incorporated into an integrated circuit;

FIG. 7 shows the nanostructure arrangement of FIG. 6 in cross section, as it might be incorporated into an integrated circuit;

FIG. 8 shows a nanostructure arrangement of another embodiment with a plurality of transistors coupled in a NAND structure;

FIGS. 9A to 9E show a method of manufacturing an integrated circuit in accordance with one embodiment;

FIGS. 10A to 10C show a method of manufacturing an integrated circuit in accordance with another embodiment;

FIGS. 11A to 11D show an allotaxy process in accordance with an embodiment;

FIGS. 12A and 12B show a process for manufacturing a nanostructure in accordance with an embodiment; and

FIGS. 13A and 13B show a memory module (FIG. 13A) and a stackable memory module (FIG. 13B) in accordance with an embodiment of the invention.

### DETAILED DESCRIPTION OF ILLUSTRATIVE EMBODIMENTS

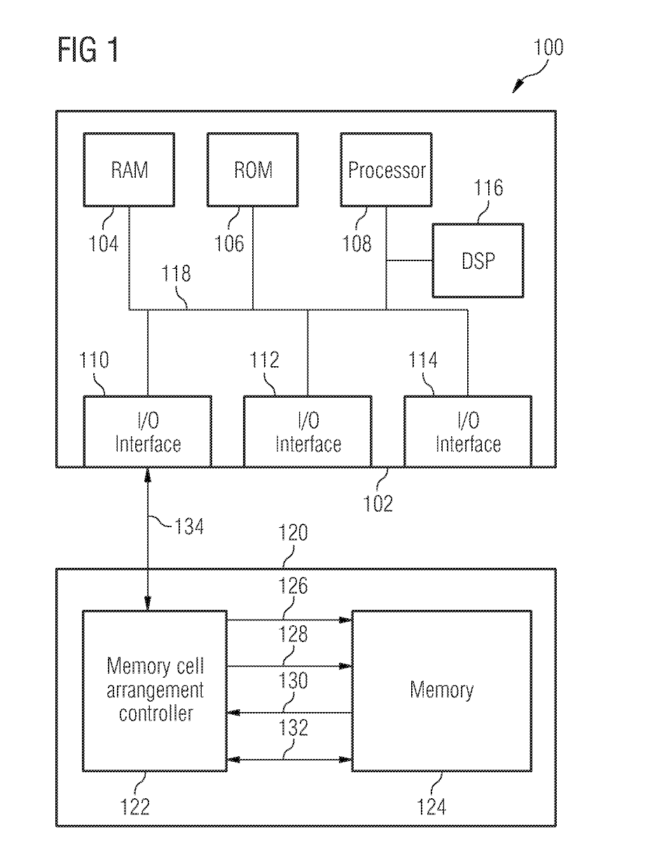

FIG. 1 shows a computer system 100 having a computer arrangement 102 and a memory cell arrangement 120 in accordance with an embodiment.

In various embodiments, the computer arrangement 102 may be configured as or may include any device having a processor, e.g., having a programmable processor such as, e.g., a microprocessor (e.g., a CISC (complex instruction set computer) microprocessor or a RISC (reduced instruction set computer) microprocessor). In various embodiments, the computer arrangement 102 may be configured as or may include a personal computer, a workstation, a laptop, a notebook, a personal digital assistant (PDA), a radio telephone (e.g., a wireless radio telephone or a mobile radio telephone), a camera (e.g., an analog camera or a digital camera), or another device having a processor (such as, e.g., a household appliance (such as e.g. a washing machine, a dishwashing machine, etc.)).

In an embodiment, the computer arrangement 102 may include one or a plurality of computer arrangement-internal random access memories (RAM) 104, e.g., one or a plurality of computer arrangement-internal dynamic random access memories (DRAM), in which for example data to be processed may be stored. Furthermore, the computer arrangement 102 may include one or a plurality of computer arrangement-internal read only memories (ROM) 106, in which for example the program code may be stored, which should be executed by a processor 108 (e.g., a processor as described above), which may also be provided in the computer arrangement 102.

Furthermore, in an embodiment, one or a plurality of input/output interfaces 110, 112, 114 (in FIG. 1, there are shown three input/output interfaces, in alternative embodiments, e.g., one, two, four, or even more than four input/output interfaces may be provided) configured to connect one or a plurality of computer arrangement-external devices (such as, e.g., additional memory, one or a plurality of communication devices, one or a plurality of additional processors) to the computer arrangement 102, may be provided in the computer arrangement 102.

The input/output interfaces 110, 112, 114 may be implemented as analog interfaces and/or as digital interfaces. The input/output interfaces 110, 112, 114 may be implemented as serial interfaces and/or as parallel interfaces. The input/output interfaces 110, 112, 114 may be implemented as one or a plurality of circuits, which implements or implement a respective communication protocol stack in its functionality in accordance with the communication protocol which is respectively used for data transmission. Each of the input/output interfaces 110, 112, 114 may be configured in accordance with any communication protocol. In an embodiment, each of the input/output interfaces 110, 112, 114 may be implemented in accordance with one of the following communication protocols:
an ad hoc communication protocol such as, e.g., Firewire or Bluetooth;
a communication protocol for a serial data transmission such as, e.g., RS-232, Universal Serial Bus (USB) (e.g., USB 1.0, USB 1.1, USB 2.0, USB 3.0);
any other communication protocol such as, e.g., Infrared Data Association (IrDA).

In an embodiment, the first input/output interface 110 is a USB interface (in alternative embodiments of the invention, the first input/output interface 110 may be configured in accordance with any other communication protocol such as, e.g., in accordance with a communication protocol which has been described above).

In an embodiment, the computer arrangement 102 optionally may include an additional digital signal processor (DSP) 116, which may be provided, e.g., for digital signal processing. Furthermore, the computer arrangement 102 may include additional communication modules (not shown) such as, e.g., one or a plurality of transmitters, one or a plurality of receivers, one or a plurality of antennas, and so on.

The computer arrangement 102 may also include additional components (not shown), which are desired or required in the respective application.

In an embodiment, some or all of the circuits or components provided in the computer arrangement 102 may be coupled with each other by one or a plurality of computer arrangement-internal connections 118 (for example, by one or a plurality of computer busses) configured to transmit data and/or control signals between the respectively coupled circuits or components.

Furthermore, as has been described above, the computer system 100, in accordance with an embodiment, may include the memory cell arrangement 120.

The memory cell arrangement 120 may in an embodiment be configured as an integrated circuit. The memory cell arrangement 120 may further be provided in a memory module having a plurality of integrated circuits, wherein at least one integrated circuit of the plurality of integrated circuits includes a memory cell arrangement 120, as will be described in more detail below. The memory module may be a stackable memory module, wherein some of the integrated circuit may be stacked one above the other. In an embodiment, the memory cell arrangement 120 is configured as a memory card.

In an embodiment, the memory cell arrangement 120 may include a memory cell arrangement controller 122 (for example, implemented by hard wired logic and/or by one or a plurality of programmable processors, e.g., by one or a plurality of programmable processors such as, e.g., one or a plurality of programmable microprocessors (e.g., CISC (complex instruction set computer) microprocessor(s) or RISC (reduced instruction set computer) microprocessor(s)).

The memory cell arrangement 120 may further include a memory 124 having a plurality of memory cells. The memory 124 will be described in more detail below.

In an embodiment, the memory cell arrangement controller 122 may be coupled with the memory 124 by various connections. Each of the connections may include one or a plurality of lines and may thus have a bus width of one or a plurality of bits. Thus, by way of example, an address bus 126 may be provided, by which one or a plurality of addresses of one or a plurality of memory cells may be provided by the memory cell arrangement controller 122 to the memory 124, on which an operation (e.g., an erase operation, a write operation, a read operation, an erase verify operation, or a write verify operation, etc.) should be carried out. Furthermore, a data write connection 128 may be provided, by which the information to be written into the respectively addressed memory cell may be supplied by the memory cell arrangement controller 122 to the memory 124. Furthermore, a data read connection 130 may be provided, by which the information stored in the respectively addressed memory cell may be read out of the memory 124 and may be supplied from the memory 124 to the memory cell arrangement controller 122 and via the memory cell arrangement controller 122 to the computer arrangement 102, or, alternatively, directly to the computer arrangement 102 (in which case the first input/output interface 110 would directly be connected to the memory 124). A bidirectional control/state connection 132 may be used for providing control signals from the memory cell arrangement controller 122 to the memory 124 or for supplying state signals representing the state of the memory 124 from the memory 124 to the memory cell arrangement controller 122.

In an embodiment, the memory cell arrangement controller 122 may be coupled to the first input/output interface 110 using a communication connection 134 (e.g., using a USB communication connection).

In an embodiment, the memory 124 may include one chip or a plurality of chips. Furthermore, the memory cell arrangement controller 122 may be implemented on the same chip (or die) as the components of the memory 124 or on a separate chip (or die).

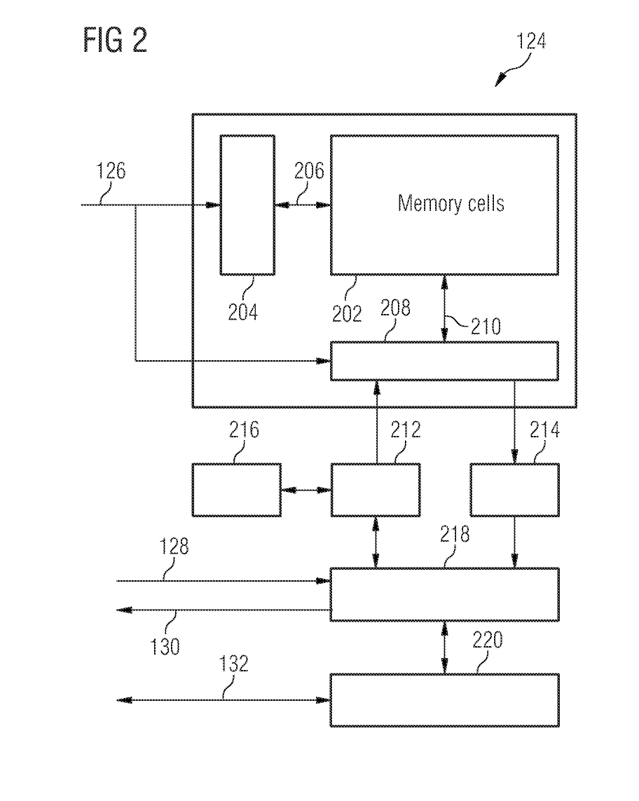

FIG. 2 shows the memory 124 of FIG. 1 in accordance with an embodiment in more detail.

In an embodiment, the memory 124 may include a memory cell field (e.g. a memory cell array) 202 having a plurality of memory cells. The memory cells may be arranged in the memory cell field 202 in the form of a matrix in rows and columns, or, alternatively, for example in zig zag form. In other embodiments, the memory cells may be arranged within the memory cell field 202 in any other manner or architecture.

In general, each memory cell may, for example, be coupled with a first control line (e.g. a word line) and with at least one second control line (e.g., at least one bit line).

In an embodiment of the invention, in which the memory cells are arranged in the memory cell field 202 in the form of a matrix in rows and columns, a row decoder circuit 204 configured to select at least one row control line (e.g., a word line) of a plurality of row control lines 206 in the memory cell field 202 may be provided as well as a column decoder circuit 208 configured to select at least one column control line (e.g., a bit line) of a plurality of column control lines 210 in the memory cell field 202.

In an embodiment, the memory cells are non-volatile memory cells.

A “non-volatile memory cell” may be understood as a memory cell storing data even if it is not active. In an embodiment, a memory cell may be understood as being not active e.g. if current access to the content of the memory cell is inactive. In another embodiment, a memory cell may be understood as being not active, e.g., if the power supply is inactive. Furthermore, the stored data may be refreshed on a regular timely basis, but not, as with a “volatile memory cell” every few picoseconds or nanoseconds or milliseconds, but rather in a range of hours, days, weeks or months. Alternatively, the data may not need to be refreshed at all in some designs.

The non-volatile memory cells may be charge storing random access memory cells (e.g., floating gate memory cells or charge trapping memory cells).

The non-volatile memory cells may be nanorod random access memory cells.

In alternative embodiments, also other types of non-volatile memory cells may be used.

In various embodiments, the memory cells may be resistive memory cells.

Furthermore, the memory cells may be electrically erasable read only memory cells (EEPROM).

In an embodiment, the memory cells may be Flash memory cells, e.g. charge storing memory cells such as, e.g., floating gate memory cells or charge trapping memory cells.

In an embodiment, each charge trapping memory cell includes a charge trapping layer structure for trapping electrical charge carriers. The charge trapping layer structure may include one or a plurality of two separate charge trapping regions. In an embodiment, the charge trapping layer structure includes a dielectric layer stack including at least one dielectric layer or at least two dielectric layers being formed above one another, wherein charge carriers can be trapped in at least one dielectric layer. By way of example, the charge trapping layer structure includes a charge trapping layer, which may include or consist of one or more materials being selected from a group of materials that consists of: aluminum oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). In one embodiment, the charge trapping layer structure includes a dielectric layer stack including three dielectric layers being formed above one another, e.g., a first oxide layer (e.g., silicon oxide), a nitride layer as charge trapping layer (e.g., silicon nitride) on the first oxide layer, and a second oxide layer (e.g., silicon oxide or aluminum oxide) on the nitride layer. This type of dielectric layer stack is also referred to as ONO layer stack. In an alternative embodiment, the charge trapping layer structure includes two, four or even more dielectric layers being formed above one another.

In an embodiment, the memory cells may be multi-bit memory cells. As used herein the term “multi-bit” memory cell is intended to, e.g., include memory cells which are configured to store a plurality of bits by spatially separated electric charge storage regions or current conductivity regions, thereby representing a plurality of logic states.

In another embodiment, the memory cells may be multi-level memory cells. As used herein the term “multi-level” memory cell is intended to, e.g., include memory cells which are configured to store a plurality of bits by showing distinguishable voltage or current levels dependent on the amount of electric charge stored in the memory cell or the amount of electric current flowing through the memory cell, thereby representing a plurality of logic states.

In an embodiment, address signals are supplied to the row decoder circuit 204 and the column decoder circuit 208 by the address bus 126, which is coupled to the row decoder circuit 204 and to the column decoder circuit 208. The address signals uniquely identify at least one memory cell to be selected for an access operation (e.g., for one of the above described operations). The row decoder circuit 204 selects at least one row and thus at least one row control line 206 in accordance with the supplied address signal. Furthermore, the column decoder circuit 208 selects at least one column and thus at least one column control line 210 in accordance with the supplied address signal.

The electrical voltages that are provided in accordance with the selected operation, e.g., for reading, programming (e.g., writing) or erasing of one memory cell or of a plurality of memory cells, are applied to the selected at least one row control line 206 and to the at least one column control line 210.

In the case that each memory cell is configured in the form of a field effect transistor (e.g., in the case of a charge storing memory cell), in an embodiment, the respective gate terminal is coupled to the row control line 206 and a first source/drain terminal is coupled to a first column control line 210. A second source/drain terminal may be coupled to a second column control line 210. Alternatively, with a first source/drain terminal of an adjacent memory cell, which may then, e.g., also be coupled to the same row control line 206 (this is the case, e.g., in a NAND arrangement of the memory cells in the memory cell field 202).

In an embodiment, by way of example, for reading or for programming, a single row control line 206 and a single column control line 210 are selected at the same time and are appropriately driven for reading or programming of the thus selected memory cell. In an alternative embodiment, it may be provided to respectively select a single row control line 206 and a plurality of column lines 210 at the same time for reading or for programming, thereby allowing to read or program a plurality of memory cells at the same time.

Furthermore, in an embodiment, the memory 124 includes at least one write buffer memory 212 and at least one read buffer memory 214. The at least one write buffer memory 212 and the at least one read buffer memory 214 are coupled with the column decoder circuit 208. Depending on the type of memory cell, reference memory cells 216 may be provided for reading the memory cells.

In order to program (e.g., write) a memory cell, the data to be programmed may be received by a data register 218, which is coupled with the data write connection 128, by the data write connection 128, and may be buffered in the at least one write buffer memory 212 during the write operation.

In order to read a memory cell, the data read from the addressed memory cell (represented, e.g., by an electrical current, which flows through the addressed memory cell and the corresponding column control line 210, which may be compared with a current threshold value in order to determine the content of the memory cell, wherein the current threshold value may, e.g., be dependent from the reference memory cells 216) are, e.g., buffered in the read buffer memory 214 during the read operation. The result of the comparison and therewith the logic state of the memory cell (wherein the logic state of the memory cell represents the memory content of the memory cell) may then be stored in the data register 218 and may be provided via the data read connection 130, with which the data register 218 may be coupled.

The access operations (e.g., write operations, read operations, or erase operations) may be controlled by a memory-internal controller 220, which in turn may be controlled by the memory cell arrangement controller 122 by the bidirectional control/state connection 132. In an alternative embodiment, the data register 218 may directly be connected to the memory cell arrangement controller 122 by the bidirectional control/state connection 132 and thus directly controlled thereby. In this example, the memory-internal controller 220 may be omitted.

In an embodiment, the memory cells of the memory cell field may be grouped into memory blocks or memory sectors, which may be commonly erased in an erase operation. In an embodiment, there are many memory cells included in a memory block or memory sector such that the same amount of data may be stored therein as compared with a conventional hard disk memory sector (e.g., 512 byte), although a memory block or memory sector may alternatively also store another amount of data.

Furthermore, other common memory components (e.g., peripheral circuits such as, e.g., charge pump circuits, etc.) may be provided in the memory 124, but they are neither shown in FIG. 1 nor FIG. 2 for reasons of clarity.

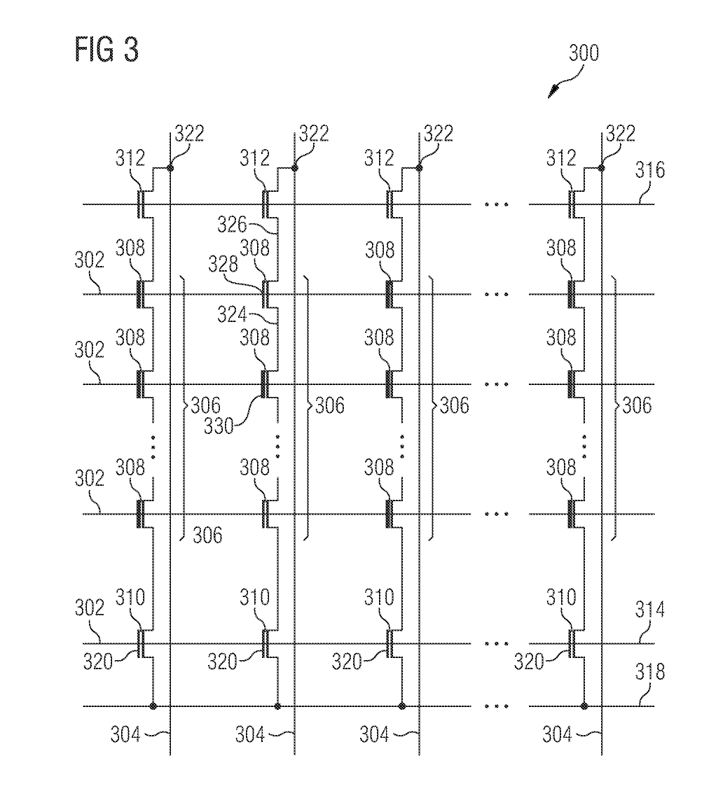

FIG. 3 shows a memory cell portion 300 of the memory cell field 202 in accordance with an embodiment.

In one embodiment, the memory cell portion 300 is arranged as a NAND memory cell field (although another coupling architecture may be provided in an alternative embodiment of the invention).

In an embodiment, the NAND memory cell portion 300 (e.g., a NAND memory cell array portion 300) may include word lines 302 (in general, an arbitrary number of word lines 302, in one embodiment of the invention, 1024 word lines 302) and intersecting bit lines 304 (in general, an arbitrary number of bit lines 304, in one embodiment of the invention, 512 bit lines 304).

The NAND memory cell array portion 300 may include nanostructures formed into NAND strings 306 (as will be described in more detail below), each NAND string 306 having memory cells 308 (e.g., charge storing memory cells 308 such as, e.g., charge trapping memory cells 308 or floating gate memory cells 308). Furthermore, an arbitrary number of memory cells 308 can be provided in the NAND string 306, in accordance with one embodiment, 32 memory cells 308. The memory cells 308 may be connected in series source-to-drain between a source select gate 310, which may be implemented as a field effect transistor, and a drain select gate 312, which may also be implemented as a field effect transistor. Each source select gate 310 is positioned at an intersection of a bit line 304 and a source select line 314. Each drain select gate 312 is positioned at an intersection of a bit line 304 and a drain select line 316. The drain of each source select gate 310 is connected to the source terminal of the first charge storing memory cells 308 of the corresponding NAND string 306. The source of each source select gate 310 is connected to a common source line 318. A control gate 320 of each source select gate 310 is connected to the source select line 314.

In one embodiment, the common source line 318 is connected between source select gates 310 for NAND strings 306 of two different NAND arrays. Thus, the two NAND arrays share the common source line 318.

In an embodiment of the invention, the drain of each drain select gate 312 may be connected to the bit line 304 of the corresponding NAND string 306 at a drain contact 322. The source of each drain select gate 312 is connected to the drain of the last charge storing memory cell 308 of the corresponding NAND string 306. In one embodiment of the invention, at least two NAND strings 306 share the same drain contact 322.

In accordance with the described embodiments, each memory cell 308 may include a source 324 (e.g., a first source/drain region), a drain 326 (e.g., a second source/drain region), a charge storage region 328 (e.g., a floating gate stack or a dielectric layer stack) and a control gate 330 (e.g., a gate region). The control gate 330 of each memory cell 308 may be connected to a respective word line 302. A column of the NAND memory cell array portion 300 may include a respective NAND string 306 and a row of the NAND memory cell array portion 300 may include those memory cells 308 that are commonly connected to a respective word line 302.

In an alternative embodiment of the invention, the memory cell portion 300 is a NOR memory cell array portion 300. In yet another embodiment of the invention, the memory cell portion 300 may be arranged in accordance with any other suitable architecture which incorporates nanostructures, regardless of how the nanostructures themselves may be organized or orientated. Various embodiments allow the efficient conduction of current to and from the nanostructures via a metalized structure.

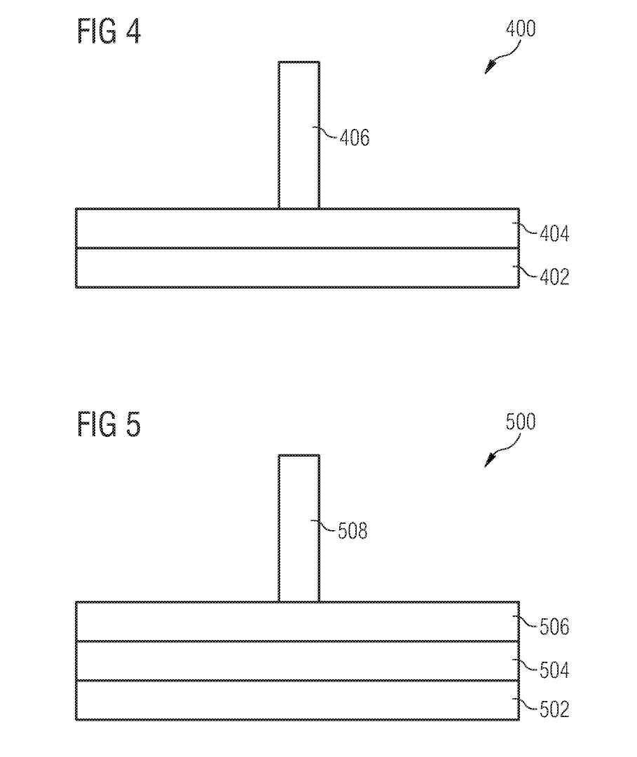

FIG. 4 shows an elongate structure (e.g., nanostructure) arrangement 400 of an embodiment as it might be incorporated into an integrated circuit and as seen with a vertically extending elongate structure (e.g., a vertically extending elongate nanostructure) 406 orientated into an upright position. In an example, a nanostructure may be understood as a structure which has a size in one or two dimensions in a nanometer range (e.g., smaller than 500 nm, e.g., smaller than 100 nm, e.g. smaller than 50 nm, e.g., smaller than 10 nm, e.g. smaller than a few nm), but which may have a size in the third dimension of more than 500 nm or even one or more micrometers. By way of example, an elongate nanostructure may have a size in a nanometer range in a width direction thereof, but a larger size its length direction (by way of example, the elongate structure may be a nanorod, a nanowire or a nanotube which has a size in a nanometer range in its width direction, but a larger size in its growth direction, in which the elongate structure may for example be grown (e.g., epitaxially grown) on a surface. Illustratively, a nanostructure may have a size in two dimensions in a nanometer range, and a larger size in the third dimension than in the other two dimensions.

A base structure 404 is positioned above a metalized structure 402 (which may also be referred to as metallically conductive structure) and in other words is adjacent to it. The metalized structure 402, because it is adjacent to the base structure 404 is arranged such that it is in electrical contact with the base structure 404. The vertically extending elongate structure (e.g., a vertically extending elongate nanostructure) 406 is positioned adjacent to the base structure 404. The vertically extending elongate structure (e.g., a vertically extending elongate nanostructure) 406 can form the basis of any suitable electronic device or electronic circuit including a vertically extending elongate structure (e.g., a vertically extending elongate nanostructure). In an embodiment, the base structure 404 may have a (predefined) crystal orientation. Furthermore, the vertically extending elongate structure (e.g., a vertically extending elongate nanostructure) 406 may have substantially the same crystal orientation as the base structure 404. In an embodiment, the metalized structure 402 may have a layer thickness in the range from about 1 nm to about 100 nm, e.g., a layer thickness in the range from about 10 nm to about 50 nm. Furthermore, the base structure may have a layer thickness in the range from about 1 nm to about 100 nm, e.g., a layer thickness in the range from about 10 nm to about 50 nm. Moreover, the vertically extending elongate structure (e.g., a vertically extending elongate nanostructure) 610 may have a length in cross section (i.e., substantially perpendicular to the growth direction of the nanostructure 610) in the range from about 1 nm to about 100 nm, e.g., in the range from about 5 nm to about 20 nm, and a width in cross section in the range from about 1 nm to about 100 nm, e.g., in the range from about 5 nm to about 20 nm.

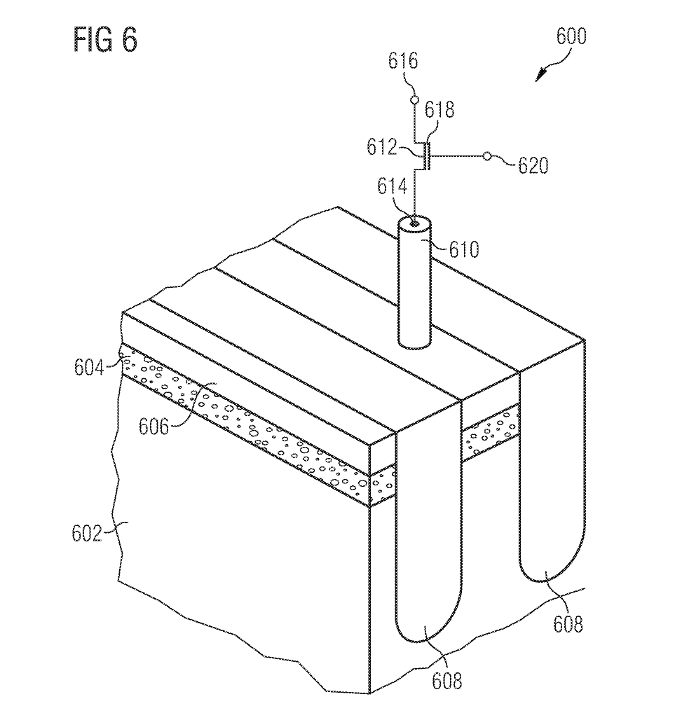

FIG. 5 shows a further embodiment of an elongate structure (e.g., nanostructure) arrangement 500, in which a base structure 506, adjacent to which a nanostructure 508 is provided, is itself positioned adjacent to a metalized structure 504 buried in a carrier (e.g., a substrate) 502 (thus, illustratively, in an example, the metalized structure 504 may be a buried metalized structure 504). The carrier 502 therefore may provide support and physical structure for the integrated circuit and thereby allows handling of the integrated circuit whereby the integrated circuit can be incorporated into bigger and more gross structures. Also in this embodiment, the base structure 506 may have a (predefined) crystal orientation. Furthermore, the elongate structure (e.g., nanostructure) 508 may have substantially the same crystal orientation as the base structure 506 and even substantially the same crystal orientation as the substrate 502. The dimensions of the elements of the elongate structure (e.g., nanostructure) arrangement 500 may be similar to the dimensions of the elongate structure (e.g., nanostructure) arrangement 400 of FIG. 4.

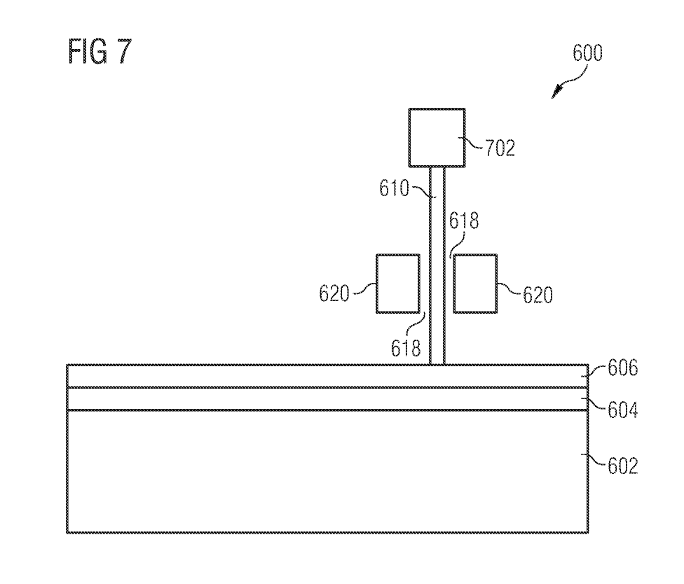

FIG. 6 shows an elongate structure (e.g., nanostructure) arrangement 600 of another embodiment, as it might be incorporated into an integrated circuit. The elongate structure (e.g., nanostructure) arrangement 600 may include a carrier (e.g., a substrate) 602. In an embodiment, the substrate (e.g., a wafer substrate) 602 may be made of semiconductor materials of various types, including silicon (e.g., single-crystalline silicon), silicon germanium or other types of semiconductor materials. In an embodiment, the single-crystalline silicon of the carrier (e.g., substrate) 602 has a carrier crystal orientation.

Furthermore, in an embodiment, a metallically conductive structure 604 is disposed in or above the carrier (e.g., substrate) 602. In an embodiment, the metallically conductive structure 604 may include a silicide, e.g., a silicide of the carrier (e.g., substrate) material. In an embodiment, the metallically conductive structure 604 may include cobalt silicide (CoSi₂). Various examples for manufacturing the metallically conductive structure 604 in the carrier 602 will be described in more detail below.

As shown in FIG. 6, the elongate structure (e.g., nanostructure) arrangement 600 further includes a base structure 606 being adjacent to the metallically conductive structure 604. In an embodiment, the base structure 606 may be made from a semiconductor material, e.g., from a single-crystalline semiconductor material such as silicon. In an embodiment, the base structure 606 may be made from the same material as the carrier (e.g., substrate) 602. Further, the base structure 606 may have the same crystal orientation as the carrier 602. As will be explained in more detail below, in an embodiment, the base structure 606 may illustratively serve as a seed material for a (e.g., epitaxial) growth of an elongate structure (e.g., nanostructure) 610 on the base structure 606.

Furthermore, isolation regions 608 such as, e.g., shallow trench isolations (which may be filled with an oxide (e.g., silicon oxide) or a nitride (e.g., silicon nitride)) may be provided to electrically isolate active areas formed by the base structure 606 from each other in a desired manner.

The elongate structure (e.g., nanostructure) 610 may also be made of a semiconductor material such as silicon and may have a single-crystalline structure. The elongate structure (e.g. nanostructure) 610 disposed on the base structure 606 may have substantially the same crystal orientation as the base structure 606. In an embodiment, the elongate structure (e.g., nanostructure) 610 may grow (e.g., epitaxially) with the same crystal orientation as the base structure 606.

The elongate structure (e.g., nanostructure) 610 (e.g., a silicon nanorod) may form a part of a transistor 612, e.g., of a field effect transistor 612, e.g., of a metal oxide semiconductor (MOS) field effect transistor 612. In an example, the field effect transistor 612 may include a first source/drain region 614, a second source/drain region 616 and an active region, in which a channel may be formed in response to the application of suitable voltages to the first source/drain region 614, the second source/drain region 616 and a control gate region 620 (disposed above an insulator region (not shown), which in turn is disposed above the single-crystalline material of the nanostructure 610). In an embodiment, the field effect transistor 612 may be configured as a memory cell transistor, e.g., as a charge storing field effect transistor 612 (e.g., as a charge trapping field effect transistor 612 or a floating gate field effect transistor 612). In this embodiment, the field effect transistor 612 may further include a charge storing structure 618 (e.g., a charge trapping structure 618 or a floating gate structure 618).

Thus, illustratively, a vertical nanorod based transistor may be provided. The vertical nanorod based transistor may be provided above the metallically conductive structure 604, which may be configured as a buried address line in order to address and control the vertical nanorod based transistor. The metallically conductive structure 604 has a low resistivity and thus a low ohmic resistance. As will be described in more detail below, in an embodiment, the metallically conductive structure 604 (e.g., the address lines) are made before the elongate structure (e.g., nanostructure) 610 is made (e.g., grown).

In the example, in which the elongate structure (e.g., nanostructure) 610 is made of single-crystalline material (e.g., single-crystalline silicon), the transistors including the elongate structure 610 in its active region show improved on/off-characteristics as compared with a transistor made of non-crystalline material (e.g., non-crystalline silicon) or poly-crystalline material (e.g., thin film transistors).

The dimensions of the elements of the elongate structure (e.g., nanostructure) arrangement 600 may be similar to the dimensions of the elongate structure (e.g., nanostructure) arrangement 400 of FIG. 4 described above.

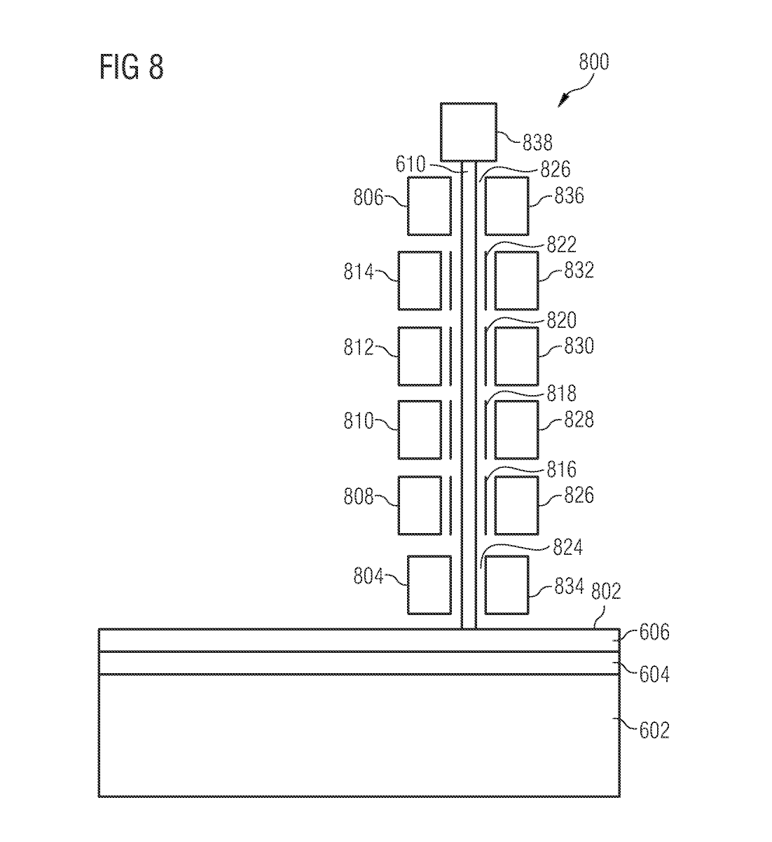

FIG. 7 shows the elongate structure (e.g., nanostructure) arrangement 600 of FIG. 6 in cross section. As shown in FIG. 7, the control gate region 620 as well as the charge storing structure 618 may be arranged fully surrounding the elongate structure (e.g., nanostructure) 610. FIG. 7 further shows an upper address contact 702, which may be coupled to the first source/drain region 614.

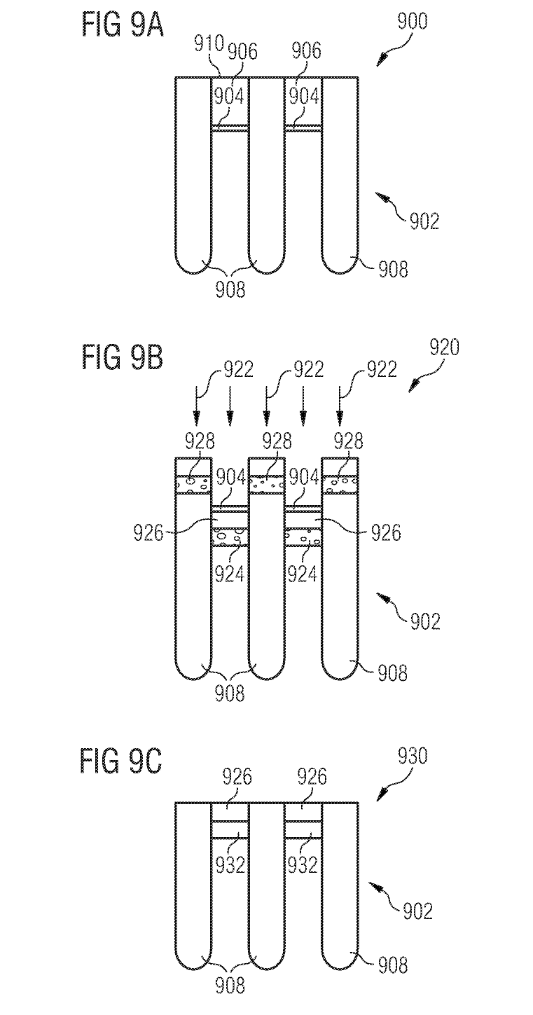

FIG. 8 shows an elongate structure (e.g., nanostructure) arrangement 800 of another embodiment with a plurality of transistors coupled in a NAND structure.

The basic structure of the elongate structure (e.g., nanostructure) arrangement 800 is similar to the structure of the elongate structure (e.g., nanostructure) arrangement 600 of FIG. 6. Therefore, in order to avoid repetition, only the additional features of the elongate structure (e.g., nanostructure) arrangement 800 compared with the elongate structure (e.g., nanostructure) arrangement 600 of FIG. 6 will be described in the following.

The elongate structure (e.g., nanostructure) arrangement 800 may include a NAND string such as one of the NAND strings 306 shown in FIG. 3, wherein the transistors of a respective string are formed along one shared elongate structure 610 which is epitaxially grown on the upper surface of the base structure 606. In the example shown in FIG. 8, a first select transistor 804 (such as, e.g., the source select gate 310) is formed as the first transistor seen from the upper surface of the base structure 606. Furthermore, a plurality of charge storing transistors 808, 810, 812, 814, are arranged along the nanostructure 610, followed by a second select transistor 806 (such as, e.g., the drain select gate 312). In an embodiment, thus, the mentioned transistors have a shared active region formed by the (single-crystalline) elongate structure 610. Thus, in an embodiment, a vertical NAND string structure is provided with a single-crystalline active region, which may form the channels of the respective transistors.

The select transistors 804, 806, may be configured as “normal” field effect transistors with insulator regions 824, 826, surrounding the elongate structure 610 and gate regions 834, 836, surrounding the insulator regions 824, 826, respectively. The charge storing transistors 808, 810, 812, 814 may each include a charge storing structure 816, 818, 820, 822, surrounding the elongate structure 610 and control gate regions 828, 830, 832, surrounding the respective charge storing structure 816, 818, 820, 822. It should be mentioned that in an example, source/drain regions may be provided as separately doped regions (adjacent transistors may share source/drain regions), whereas in another example, the specific source/drain regions may be omitted and may only be formed by the elongate structure 610 having substantially the same doping level as the active regions. The elongate structure 610 is coupled at the end opposite to the base structure 606 surface with an address line 838 and/or an address line contact.

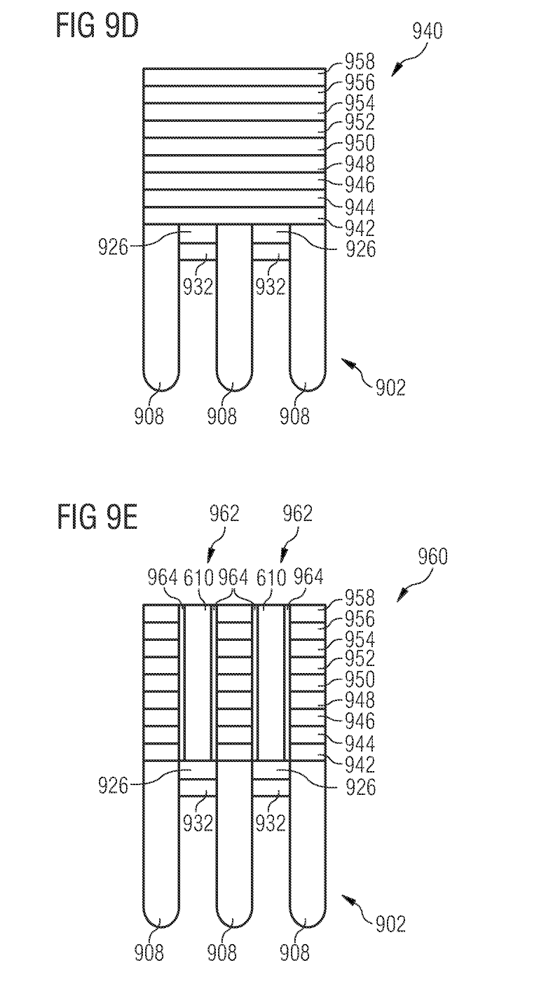

FIGS. 9A to 9E shows a method of manufacturing an integrated circuit in accordance with one embodiment.

Referring now to FIG. 9A, a first partial structure 900 includes a carrier (e.g., a substrate) (e.g., made of silicon) 902, on the upper surface of which a pad oxide (e.g., silicon oxide) 904 is deposited, followed by a deposition of a pad nitride (e.g., silicon nitride) 906 on the pad oxide 904. Then, in a lithography step, the active area is defined. Then, the thus defined shallow trench isolation regions are etched and the etched trenches are filled with isolating material (e.g., with silicon oxide), thereby forming shallow trench isolations (STI) 908. The overfilling isolating material is then planarized, e.g., using a chemical mechanical polishing (CMP) process, thereby exposing the upper surface 910 of the pad nitride which is on top of the pad oxide and the substrate material, e.g., single-crystalline silicon.

Next, using another lithographic mask, a structure of a memory array is defined and the pad nitride 906 is removed.

In a following process, metal atoms (e.g., cobalt (Co)) are implanted through the pad oxide 904 (symbolized by arrows 922 in a second partial structure 920 in FIG. 9B), thereby forming metal atom implanted regions 924 at a predefined depth (e.g., at a predefined depth in the range from about 0 nm to about 100 nm calculated from the upper surface of the pad oxide 904, e.g., at a predefined depth in the range from about 10 nm to about 40 nm) within the substrate 902. Single-crystalline substrate material regions 926 remain between the metal atom implanted regions 924 and the upper surface 910 of the carrier (e.g., substrate) material. Then, a buried metal silicide region 932 (e.g., a buried cobalt silicide) is formed in the metal atom implanted regions 924. Thus, an epitaxial buried CoSi₂ bit line may be formed by a so called ion beam synthesis process while maintaining the former carrier surface region as seed layer 926 for the nanorod 610 growth, as shown in a third partial structure 930 in FIG. 9C.

In an embodiment, a high dose of metal ions such as, e.g., cobalt ions into the heated carrier (e.g., a heated silicon wafer) is implanted such that a Gaussian type depth distribution of precipitates is obtained. By a subsequent high temperature anneal causing an Ostwald ripening like precipitate growth a (e.g., substantially perfect) heteroepitaxial system Si (substrate)/CoSi₂/Si (seed) can be achieved.

In an embodiment, a CoSi₂ bit line patterning can be carried out by processing the implantation after the active area/shallow trench isolation (AA/STI) patterning as described above. The implanted precipitates 928 in the STI oxide may then be removed by partial (or complete) backetch of the STI oxide as shown in the third partial structure 930 in FIG. 9C.

In another embodiment (not shown) an implantation of metal (e.g., cobalt) may be provided through a line space mask (e.g., tungsten/silicon oxide (W/SiO₂)) into an unpatterned active area (AA).

Then, a partial (or complete) removal of the pad oxide (e.g., silicon oxide) 904 may be provided, thereby exposing the upper surface of the single-crystalline carrier material regions 926, which may serve as a seed layer for a subsequent epitaxial growth of the elongate structure 610.

Next, the fabrication processes to form the above mentioned transistor structure (e.g., of the elongate structure (e.g., nanostructure) arrangement 600 or 800) are carried out.

First, as shown in a fourth partial structure 940 in FIG. 9D, an inter-level isolation layer 942 (e.g., made of a suitable dielectric such as, e.g., an oxide (e.g., silicon oxide) or a nitride (e.g., silicon nitride) is deposited on the upper surface of the third partial structure 930 shown in FIG. 9C. Then, a gate layer 944 (in general, an electrically conductive layer) is deposited on the upper surface of the inter-level isolation layer 942. Next, a further inter-level isolation layer 946 is deposited on the upper surface of the gate layer 944. In an embodiment, a stack of alternating inter-level isolation layers 950, 954, 958 and gate layers 948, 952, 956 are stacked one above the other depending on the number of transistors which should be formed in the vertical elongate structure (e.g., nanostructure) arrangement (e.g., 600 or 800) to be formed (one gate layer is provided for each transistor to be formed).

Then, as shown in a fifth partial structure 960 in FIG. 9E, using a lithographic process, the region, in which the elongate structure 610 should be formed, is defined and etched (e.g., using a reactive ion etching (RIE) process), thereby forming trenches 962 (at least some portions of the upper surface of the single-crystalline substrate material regions 926 may be exposed in an example by the trenches 962). In an embodiment, in this lithography process, also a patterning of the respectively provided inter-level isolation layer(s) and gate layer(s) may be simultaneously be provided in order to isolate the respective NAND strings from each other.

After having etched the trenches 962 (thereby exposing an upper surface of the single-crystalline substrate material 926) in which the elongate structure 610 will be grown later on, a gate dielectric structure 964 (e.g., a charge trapping structure including, e.g., an oxide/nitride/oxide (ONO) layer stack 964 or another layer stack including the materials of a charge trapping structure as described above) is formed, followed by a spacer etch process. The ONO layer stack 964 may be used (depending on the voltages applied to the respective transistor terminals) to form a charge trapping transistor (and thus as a memory cell, for example) or as a “normal” field effect transistor (and thus as a select transistor, for example).

Next, a selective epitaxial growth process is carried out, thereby selectively epitaxially growing the nanostructure 610 on the exposed upper surface of the single-crystalline carrier (e.g., substrate) material (in this context illustratively serving as a seed layer), thereby forming the active regions of the transistors to be formed.

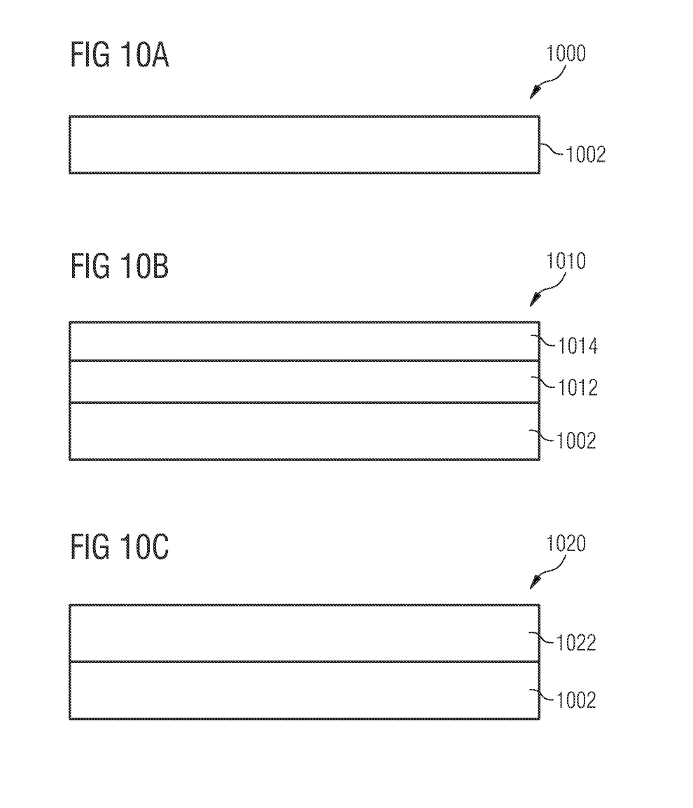

FIGS. 10A to 10C shows a method 1000 of manufacturing an integrated circuit in accordance with another embodiment.

Referring now to FIG. 10A, a first partial structure 1000 includes a carrier (e.g. substrate) 1002. The carrier (e.g., substrate) 1002 is heated and a layer of metal 1012 is deposited onto the upper surface of the carrier 1002, thereby forming a second partial structure 1010 as shown in FIG. 10B. Furthermore, a further layer 1014 (e.g. made of the same material as the carrier (e.g., substrate) material, e.g., made of silicon) is deposited. In an embodiment, both the layers of metal 1012 and the further layer 1014 may be deposited with time dependent fluxes. Both layers 1012 and 1022 may then be annealed to obtain a buried silicide layer 1022 (e.g., cobalt silicide (CoSi₂) layer 1022), as shown in a third partial structure 1020 in FIG. 10C. In an embodiment, a cobalt silicide allotaxy process may be used to form the buried cobalt silicide (CoSi₂) layer 1022.

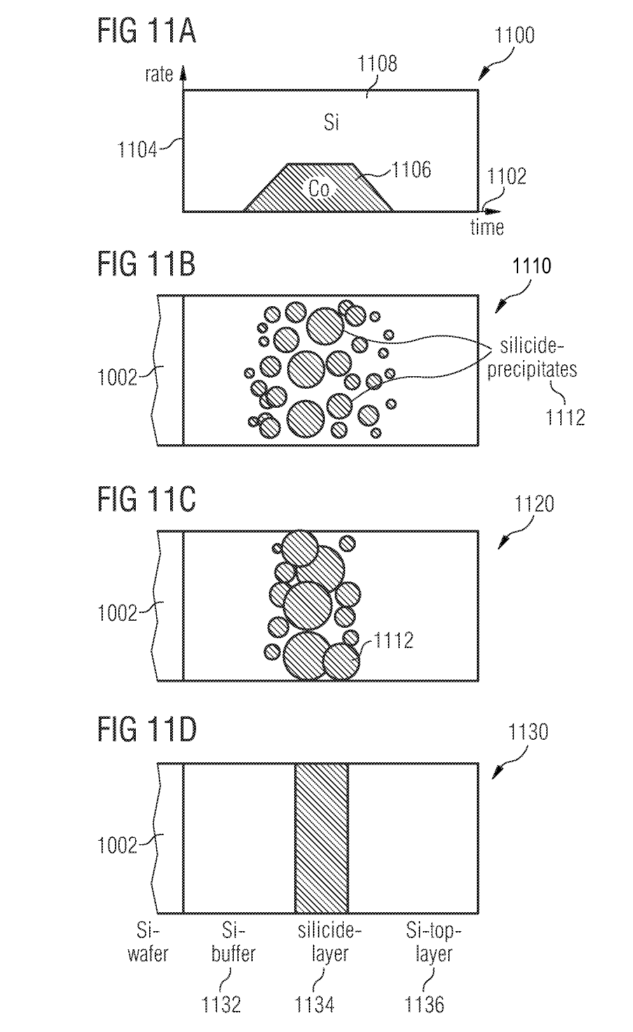

In a cobalt silicide allotaxy process, the epitaxial seed layer to be formed on top of the CoSi₂ layer 1022 may be obtained by co-deposition of cobalt and silicon onto the heated substrate 1002 with time dependent cobalt and silicon fluxes, as shown in a first allotaxy structure 1110 in FIG. 11B. FIG. 11A shows in a time/rate diagram 1100 an example of a ratio between cobalt 1106 and silicon 1108 on a ratio axis 1104 shown over a time axis 1102. Since the cobalt/silicon ratio is always kept below the value needed for silicide formation an epitaxial silicon growth takes place throughout the whole deposition process with silicide precipitates 1112 showing a size distribution shown in the first allotaxy structure 1110 in FIG. 11B. By a high temperature rapid thermal anneal process (RTP) anneal a high quality (in an embodiment substantially perfect) epitaxial buried CoSi₂ layer 1134 is obtained by an Ostwald ripening like process (which is symbolized in a second allotaxy structure 1112 in FIG. 11C). In this process, the single crystalline state of a silicon on top layer 1136 which is formed on the top of the epitaxial buried CoSi₂ layer 1134, is maintained. Maintaining this single crystalline state of the upper silicon layer allows that particularly pure silicon elongate structure (e.g., particularly pure silicon nanostructures) can be (epitaxially) grown thereupon. It should be mentioned, that in accordance with this process, a silicon buffer layer 1132 remains between the carrier 1002 and the epitaxial buried CoSi₂ layer 1134.

The buried silicide layer 1022 may have a substantially continuous metallization layer buried within it and the address lines may be produced out of this metallization layer by a lithography step, not shown, to remove the portions of the metalized carrier via shallow trench isolation where the metalized structure should not be provided required. The procedure for manufacturing the shallow trench isolations is followed resulting in filled isolation trenches around and adjacent to the resulting metalized address lines and planarization of the surface.

Next, the fabrication processes to form the above mentioned transistor structure (e.g. of the nanostructure arrangement 600 or 800) are carried out, by way of example, the fabrication processes described above or the fabrication processes which will be described in more detail further below.

A further method for forming the device of the invention may include a formation of an epitaxial cobalt silicide layer on top of a silicon carrier (e.g., substrate) followed by the heteroepitaxial formation of a layer of silicon on top of the single crystalline layer of cobalt silicide. This may produce a substrate having a buried metalized structure and then, as described above, a lithography step is used to define the address lines including the metalized structure using shallow trench isolation.

In this embodiment, an epitaxial multilayer growth is provided, e.g., on a (111) surface using Miller indices. Epitaxial CoSi₂ on silicon can be grown by a so-called template method, i.e., a combination of solid state reaction and co-deposition, followed by a heteroepitaxy of silicon on top of the single crystalline CoSi₂ layer (in (111) crystal orientation) in a molecular beam epitaxy (MBE) system.

Next, the fabrication processes to form the above mentioned transistor structure (e.g., of the nanostructure arrangement 600 or 800) are carried out, by way of example, the fabrication processes described above or the fabrication processes which will be described in more detail further below.

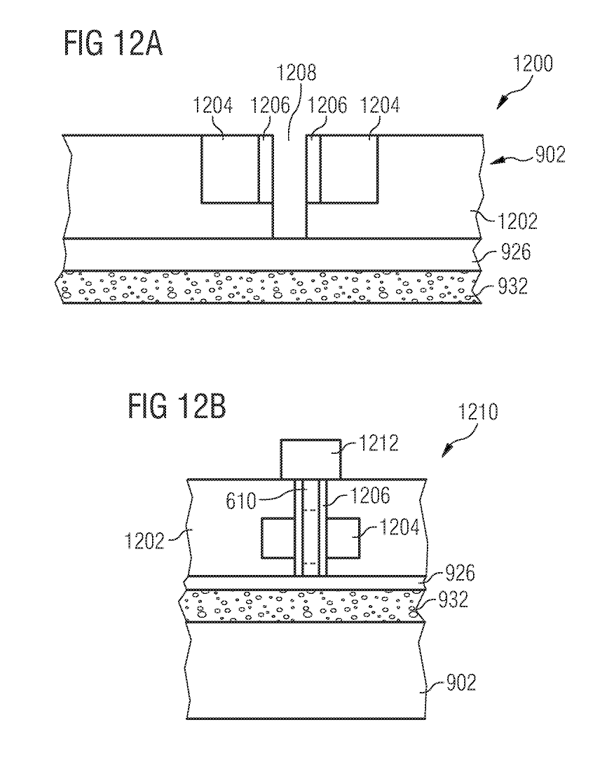

FIGS. 12A and 12B show a process for manufacturing an elongate structure (e.g., nanostructure) in accordance with an embodiment.

In this embodiment, as shown in a first partial structure 1200 in FIG. 12A, an inter-level isolation layer 1202 (e.g., made of an oxide (e.g., silicon oxide) or of a nitride (e.g., silicon nitride) is deposited on the single-crystalline substrate material regions 926. Next, portions of the inter-level isolation layer 1202, are removed (e.g., etched away), in which the gate layer 1204 (e.g., made of polysilicon) should be formed. Then, polysilicon is deposited to form the gate layer 1204, followed by a planarization process (e.g., chemical mechanical polishing (CMP) process). Next, a contact hole 1208 is formed (e.g., by an anisotropic etching, e.g., by a reactive ion etching (RIE)) in the gate layer 1204 down to the lower polysilicon boundary. Then, an oxidation process (e.g., also referred to as gate oxidation) is carried out to form gate isolation regions 1206. In a subsequent process, the contact hole 1208 is further etched (e.g., by an anisotropic etching, e.g., by a reactive ion etching (RIE)) down to the seed layer level, in other words, to expose the upper surface of the single-crystalline carrier (e.g., substrate) material regions 926.

Then, as shown in a second partial structure 1210 in FIG. 12B, a selective epitaxial growth of the nanorod 610 as an elongate structure (e.g., nanostructure) is carried out. In an embodiment, the selective epitaxial growth is carried out such that a modulation of the dopant level within the nanorod 610 is allowed to form the source/drain regions of the transistor to be formed. The modulation may be carried out by changing (e.g., switching on and off) the supply of process gases providing the desired doping atoms) by means of an in-situ doping of the nanorod material during the selective epitaxial growth process, thereby forming the desired source/drain regions in the nanorod 610, for example.

It should be mentioned that the described process can be modified to form one or more transistors (e.g., one or more memory cells), e.g., additional layers of one or more transistors may be deposited.

Finally, after a metal/top contact patterning, a metal/top contact 1212 is deposited.

In an embodiment, the provision of one or more vertical transistors may allow to extend integration of transistor arrays into the third dimension (the first and the second dimension being determined, e.g., by the main processing surface of the carrier), i.e., for stacked memory cell arrangements. Thereby, the carrier material (or the base structure material, which may be the same material as the carrier material) may be used as a seed layer for epitaxial growth of the elongate structure (e.g., the nanostructure, e.g., a nanorod) within a preprocessed hole of the gate structure. For using silicon as a nanorod material, single-crystalline silicon may be provided as a seed material to obtain a high crystal quality desired for the nanorod by homoepitaxy. In an embodiment, the above-mentioned buried address line (e.g. bit line) may be a doped silicon substrate. However, a substantial reduction of the address line (e.g., bit line) resistance as obtained by the introduction of a metalized address line (e.g., bit line) is provided to achieve smaller array sizes. In an implementation, this is achieved by introducing a method to obtain a cobalt silicide (CoSi₂) layer that allows a single-crystal silicon seed on top of it.

The described methods allow the production of a device with a dense array of metalized lines allowing production of very small and compact integrated circuits. Inclusion of silicon as the carrier, base structure and elongate structure (e.g., nanostructure) may allow a convenient, focused manufacture process. Use of cobalt silicide may allow a device to be produced with a lattice mismatch of less than 2% and the formation of a buried metal line with a resistivity of less than 100 μOhmcm.

Furthermore, in an embodiment, a homogeneous growth of the elongate structures (e.g., nanostructures) even within a large array is possible.

Further, it is to be noted, that the above described select transistors in the vertical NAND string nanorod structure are optional. The buried metalized structure provides a low ohmic lower connection level and an isolated bit line, which allows a hot charge carrier programming.

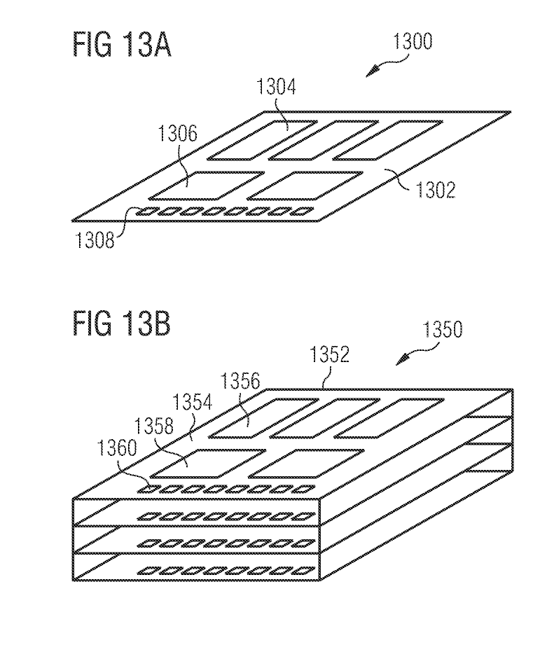

As shown in FIGS. 13A and 13B, in some embodiments, memory devices such as those described herein may be used in modules.

In FIG. 13A, a memory module 1300 is shown, on which one or more memory devices 1304 are arranged on a substrate 1302. The memory device 1304 may include numerous memory cells, each of which uses a memory element in accordance with an embodiment of the invention. The memory module 1300 may also include one or more electronic devices 1306, which may include memory, processing circuitry, control circuitry, addressing circuitry, bus interconnection circuitry, or other circuitry or electronic devices that may be combined on a module with a memory device, such as the memory device 1304. Additionally, the memory module 1300 includes multiple electrical connections 1308, which may be used to connect the memory module 1300 to other electronic components, including other modules.

As shown in FIG. 13B, in some embodiments, these modules may be stackable, to form a stack 1350. For example, a stackable memory module 1352 may contain one or more memory devices 1356, arranged on a stackable substrate 1354. The memory device 1356 contains memory cells that employ memory elements in accordance with an embodiment of the invention. The stackable memory module 1352 may also include one or more electronic devices 1358, which may include memory, processing circuitry, control circuitry, addressing circuitry, bus interconnection circuitry, or other circuitry or electronic devices that may be combined on a module with a memory device, such as the memory device 1356. Electrical connections 1360 are used to connect the stackable memory module 1352 with other modules in the stack 1350, or with other electronic devices. Other modules in the stack 1350 may include additional stackable memory modules, similar to the stackable memory module 1352 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit, comprising:
a carrier having a buried electrically conductive structure, wherein a portion of the carrier has a crystal orientation;
a vertically extending elongate structure disposed on the portion of the carrier having the crystal orientation;
wherein the vertically extending elongate structure has substantially the same crystal orientation as the portion of the carrier having the crystal orientation.

2. The integrated circuit of claim 1, wherein the vertically extending elongate structure comprises a vertically extending elongate nanostructure.

3. The integrated circuit of claim 1, further comprising:
a memory cell;
wherein the vertically extending elongate structure is part of the memory cell.

4. The integrated circuit of claim 1, wherein the carrier comprises silicon.

5. The integrated circuit of claim 1, wherein the electrically conductive structure comprises an address line structure to electrically couple the vertically extending elongate structure.

6. The integrated circuit of claim 3,
wherein the memory cell comprises a transistor;
wherein the vertically extending elongate structure is part of a transistor of the memory cell.

7. The integrated circuit of claim 1, further comprising:
a plurality of memory cells;
wherein each memory cell comprises a transistor.

8. The integrated circuit of claim 7, wherein the plurality of memory cells are coupled to each other in accordance with a NAND coupling structure.

9. An integrated circuit, comprising:
an electrically conductive structure;
a base structure having a crystal orientation, the base structure being adjacent to the electrically conductive structure; and
a vertically extending elongate structure disposed on the base structure, the vertically extending elongate structure having substantially the same crystal orientation as the base structure.

10. The integrated circuit of claim 9, further comprising:
a carrier with a carrier crystal orientation, the crystal orientation of the base structure being arranged to be substantially the same as the carrier crystal orientation.

11. The integrated circuit of claim 9, wherein the vertically extending elongate structure comprises a vertically extending elongate nanostructure.

12. The integrated circuit of claim 9, further comprising:
a memory cell;
wherein the vertically extending elongate structure is part of a memory cell.

13. The integrated circuit of claim 9, wherein the electrically conductive structure is disposed on or in a carrier.

14. A method for manufacturing an integrated circuit, the method comprising:
forming a base structure and an electrically conductive structure adjacent to each other, wherein the base structure has a crystal orientation; and
epitaxially growing a vertically extending elongate structure from the base structure, the vertically extending elongate structure having substantially the same crystal orientation as the base structure.

15. The method of claim 14, wherein the vertically extending elongate structure is formed as a vertically extending elongate nanostructure.

16. The method of claim 14, wherein the base structure and the electrically conducting structure are formed in a carrier.

17. The method of claim 16, wherein the electrically conductive structure is formed in the carrier by ion implantation.

18. The method of claim 17, wherein the electrically conductive structure is formed in the carrier by ion implantation of cobalt ions.

19. The method of claim 16, wherein the carrier comprises silicon.

20. The method of claim 14, wherein the electrically conductive structure and the base structure are deposited on a carrier.

21. The method of claim 14,
wherein the electrically conductive structure is epitaxially grown on a carrier; and
wherein the base structure is epitaxially grown on the electrically conductive structure.

22. An integrated circuit, comprising:
a metal line for providing current;
a single crystalline base region disposed in electrical contact with the metal line; and
a vertically extending elongate structure epitaxially grown on the single crystalline base region, the vertically extending elongate structure being configured to conduct current.

23. The integrated circuit of claim 22, wherein the vertically extending elongate structure comprises a vertically extending elongate nanostructure.

24. The integrated circuit of claim 22, further comprising:
a memory cell;
wherein the vertically extending elongate structure is part of the memory cell.

25. A method for manufacturing an integrated circuit, the method comprising:
forming a single crystalline base region in electrical contact with a metal line; and
epitaxially growing a vertically extending elongate structure capable of conducting electric current on the single crystalline base region.
